(19) United States
(12) Patent Application Publication
(10) Pub. No.: US 2024/0429200 A1
(43) Pub. Date: Dec. 26, 2024

(54) SEMICONDUCTOR PACKAGE

(71) Applicant: SAMSUNG ELECTRONICS CO., LTD., Suwon-si (KR)

(72) Inventors: Jing Cheng LIN, Suwon-si (KR); Youngkun JEE, Suwon-si (KR)

(73) Assignee: SAMSUNG ELECTRONICS CO., LTD., Suwon-si (KR)

(21) Appl. No.: 18/665,102

(22) Filed: May 15, 2024

(30) Foreign Application Priority Data
Jun. 26, 2023 (KR) 10-2023-0082132

(51) Int. Cl. H01L 25/065; H01L 23/00; H01L 23/31; H01L 23/495; H01L 23/538; H10B 80/00

(52) U.S. Cl. CPC H01L 25/0652; H01L 23/3128; H01L 23/3157; H01L 23/49517; H01L 23/5383; H01L 24/16; H10B 80/00; H01L 2224/16145; H01L 2224/16238

(57) ABSTRACT

A semiconductor package includes a redistribution structure including: a passivation layer; an under bump metallurgy (UBM) layer on a portion of a lower surface of the passivation layer; and a conductive layer in contact with the UBM layer and exposed from an upper surface of the passivation layer opposite to the lower surface of the passivation layer. The semiconductor package further includes: a bridge chip on the redistribution structure and including a bridge chip pad; a first molding layer sealing the bridge chip on the redistribution structure; conductive posts spaced apart from each other in a horizontal direction within the first molding layer, the bridge chip being between the conductive posts and each of the conductive posts; and a semiconductor chips on the first molding layer and the bridge chip, each of the semiconductor chips including a chip pad and a solder bump.

### CROSS-REFERENCE TO RELATED APPLICATION

This application is based on and claims priority under 35 U.S.C. § 119 to Korean Patent Application No. 10-2023-0082132, filed on Jun. 26, 2023, in the Korean Intellectual Property Office, the disclosure of which is incorporated by reference herein in its entirety.

### BACKGROUND

### 1. Field

Embodiments of the present disclosure relate to a semiconductor package, and more particularly, to a semiconductor package including a bridge chip.

### 2. Description of Related Art

In accordance with the rapid development of the electronic industry and the needs of users, electronic devices are becoming more compact and lightweight. Accordingly, semiconductor packages used in electronic devices are also becoming more compact and lightweight. In addition, semiconductor packages require high reliability along with high performance and large capacity. As such semiconductor packages have high performance and large capacity, the power consumption of the semiconductor packages has increased. Accordingly, the importance of structures of semiconductor packages to achieve size reduction and performance improvement of the semiconductor packages and to stably supply power to the semiconductor packages is increasing.

### SUMMARY

Embodiments of the present disclosure provide a semiconductor package with reduced process costs and improved reliability.

According to embodiments of the present disclosure, a semiconductor package may be provided. The semiconductor package includes a redistribution structure including: a passivation layer that is a single layer structure; an under bump metallurgy (UBM) layer on a portion of a lower surface of the passivation layer; and a conductive layer in contact with the UBM layer and exposed from an upper surface of the passivation layer opposite to the lower surface of the passivation layer. The semiconductor package further includes: a bridge chip on the redistribution structure and including a bridge chip pad; a first molding layer sealing the bridge chip on the redistribution structure; a plurality of conductive posts spaced apart from each other in a horizontal direction within the first molding layer, the bridge chip being between the plurality of conductive posts and each of the plurality of conductive posts including a first surface and a second surface opposite to the first surface; and a plurality of semiconductor chips on the first molding layer and the bridge chip, each of the plurality of semiconductor chips including a chip pad and a solder bump, wherein the first surface of each of the plurality of conductive posts is bonded to the conductive layer, and the second surface of each of the plurality of conductive posts is bonded to the solder bump of a respective one of the plurality of semiconductor chips, and wherein the solder bump is configured to enable self-alignment between one conductive post from among the plurality of conductive posts and the chip pad.

According to embodiments of the present disclosure, a semiconductor package may be provided. The semiconductor package includes a redistribution structure including: a passivation layer that is a single layer structure; an under bump metallurgy (UBM) layer on a portion of a lower surface of the passivation layer; and a conductive layer in contact with the UBM layer and exposed from an upper surface of the passivation layer opposite to the lower surface of the passivation layer. The semiconductor package further includes: a plurality of semiconductor chips spaced apart on the redistribution structure in a horizontal direction and each including chip pads, first solder bumps, and second solder bumps; a bridge chip between the plurality of semiconductor chips and the redistribution structure and including a plurality of bridge chip pads; a plurality of conductive posts spaced apart from each other in the horizontal direction, the bridge chip being between the plurality of conductive posts and each of the plurality of conductive posts includes a first surface bonded to the conductive layer and a second surface bonded to a respective one of the first solder bumps; a plurality of vertical connection conductors between the plurality of semiconductor chips and the bridge chip, each of the plurality of vertical connection conductors including: a third surface bonded to a respective one of the plurality of bridge chip pads; and a fourth surface bonded to a respective one of the second solder bumps; and a first molding layer disposed on the redistribution structure and sealing the bridge chip, the plurality of conductive posts, and the plurality of vertical connection conductors, wherein the first solder bumps are configured to enable self-alignment between the plurality of conductive posts and at least some of the chip pads.

According to embodiments of the present disclosure, a semiconductor package may be provided. The semiconductor package includes a redistribution structure including: a passivation layer that is a single layer structure; an under bump metallurgy (UBM) layer on a portion of a lower surface of the passivation layer; and a conductive layer in contact with the UBM layer and exposed from an upper surface of the passivation layer opposite to the lower surface of the passivation layer. The semiconductor package further includes: a first semiconductor chip on the redistribution structure and including a first solder bump, a second solder bump, a first chip pad bonded to the first solder bump, and a second chip pad bonded to the second solder bump; a second semiconductor chip on the redistribution structure, spaced apart from the first semiconductor chip in a horizontal direction, and including a third solder bump, a fourth solder bump, a third chip pad bonded to the third solder bump, and a fourth chip pad bonded to the fourth solder bump; a bridge chip between the redistribution structure and the first semiconductor chip and including bridge chip pads and a bridge circuit electrically connected to the bridge chip pads, the bridge chip configured to provide an electrical connection path between the first semiconductor chip and the second semiconductor chip; a first sealing layer sealing the bridge chip; a first conductive post passing through the first sealing layer in a vertical direction on one side of the bridge chip; and a second conductive post passing through the first sealing layer in the vertical direction on another side of the bridge chip opposite to the one side, wherein the first conductive post includes a lower surface and an upper surface opposite to the lower surface of the first conductive post, wherein the lower surface is bonded to the conductive layer and the upper surface is bonded to the first solder bump, wherein the second conductive post includes a lower surface and an upper surface opposite to the lower surface of the second conductive post, wherein the lower surface is bonded to the conductive layer and the upper surface is bonded to the third solder bump, wherein a horizontal distance between the second solder bump and the bridge chip is smaller than a horizontal distance between the first solder bump and the bridge chip, wherein a horizontal distance between the fourth solder bump and the bridge chip is smaller than a horizontal distance between the third solder bump and the bridge chip, wherein the first solder bump is configured to enable self-alignment between the first conductive post and the first chip pad, and wherein the third solder bump is configured to enable self-alignment between the second conductive post and the second chip pad.

### BRIEF DESCRIPTION OF DRAWINGS

Embodiments will be more clearly understood from the following detailed description taken in conjunction with the accompanying drawings in which:

FIG. 1A is a plan view of a semiconductor package according to an embodiment;

FIG. 1B is a cross-sectional view of the semiconductor package taken along line A-A′ of FIG. 1A;

FIGS. 2 to 6 are cross-sectional views of a semiconductor package according to embodiments;

FIG. 7A is a plan view of a semiconductor package according to an embodiment;

FIG. 7B is a cross-sectional view of the semiconductor package taken along line B-B′ of FIG. 7A; and

FIGS. 8A to 8N are cross-sectional views sequentially illustrating a method of manufacturing the semiconductor package illustrated in FIGS. 1A and 1B.

### DETAILED DESCRIPTION

Hereinafter, non-limiting example embodiments of the present disclosure will be described in detail with reference to the accompanying drawings. However, embodiments of the present disclosure are not limited to the example embodiments described below and may be embodied in various forms. The following example embodiments are described to fully convey the scope of the present disclosure to those of ordinary skill in the art.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

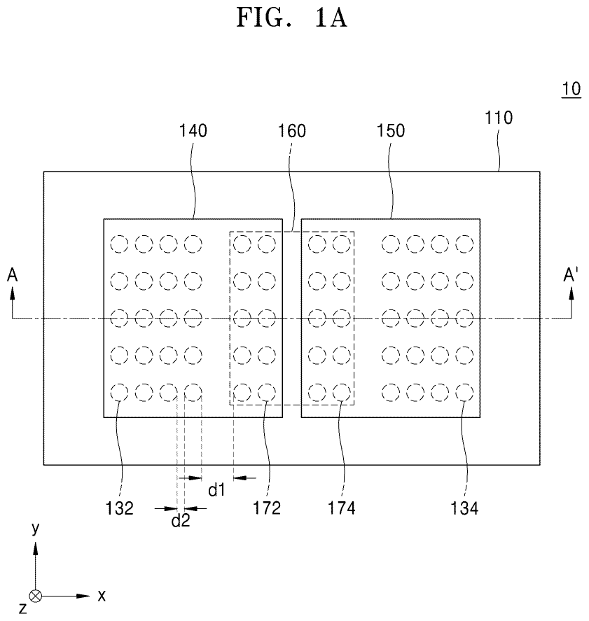

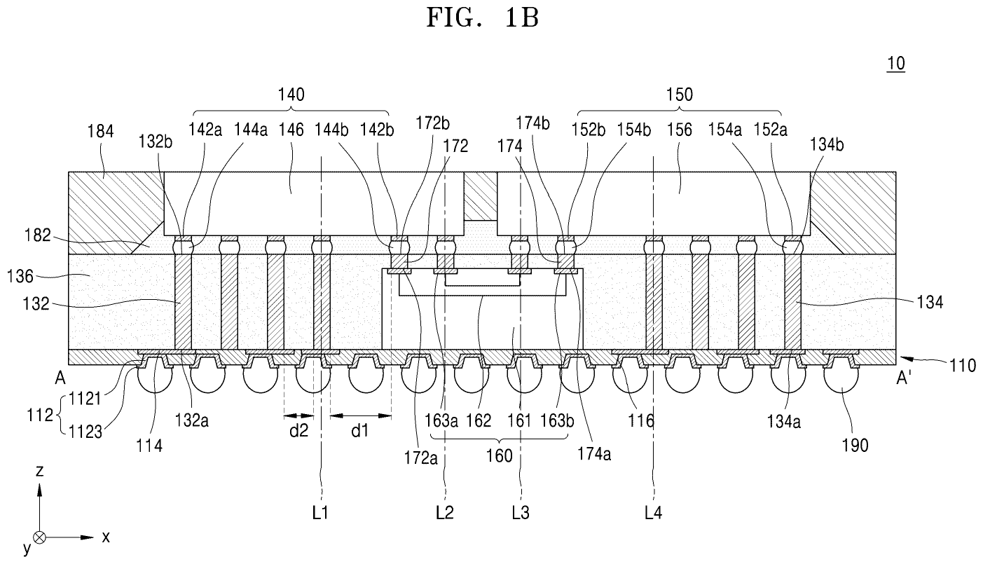

FIG. 1A is a plan view of a semiconductor package 10 according to an embodiment, and FIG. 1B is a cross-sectional view of the semiconductor package 10 taken along line A-A′ of FIG. 1A.

Referring to FIGS. 1A and 1B, the semiconductor package 10 may include a redistribution structure 110, a bridge chip 160, a first molding layer 136, a plurality of conductive posts (e.g., a first conductive post 132 and a second conductive post 134), a plurality of vertical connection conductors (e.g., a first vertical connection conductor 172 and a second vertical connection conductor 174), a plurality of semiconductor chips (e.g., a first semiconductor chip 140 and a second semiconductor chip 150), and a second molding layer 184. The semiconductor package 10 may have a fan-out structure. A footprint of the redistribution structure 110 may be larger in size than the semiconductor chips (e.g., the first semiconductor chip 140 and the second semiconductor chip 150). The footprint of the redistribution structure 110 may be the same as the footprint of the semiconductor package 10.

The redistribution structure 110 may be a redistribution layer for packaging mounting components such as the bridge chip 160 or the semiconductor chips (e.g., the first semiconductor chip 140 and the second semiconductor chip 150). The redistribution structure 110 may include an upper surface and a lower surface opposite to each other. The upper surface and the lower surface of the redistribution structure 110 may each be perpendicular to a vertical direction (e.g., a Z direction).

In the present specification, a direction which is perpendicular to the upper surface of the redistribution structure 110 may be defined as the vertical direction (the Z direction), and a direction which is parallel to the upper surface of the redistribution structure 110 and in which the semiconductor chips (e.g., the first semiconductor chip 140 and the second semiconductor chip 150) are arranged side-by-side may be defined as a first horizontal direction (an X direction). In addition, a direction perpendicular to the vertical direction (the Z direction) and the first horizontal direction (the X direction) and parallel to the upper surface of the redistribution structure 110 may be defined as a second horizontal direction (a Y direction).

The redistribution structure 110 may include an under bump metallurgy (UBM) layer 112, a conductive layer 114, and a passivation layer 116 covering the UBM layer 112 and the conductive layer 114. The passivation layer 116 may consist of a single layer structure. The passivation layer 116 may completely cover the lower surface and the side surface of the conductive layer 114 and may expose the upper surface of the conductive layer 114. In addition, a portion of the lower surface of the passivation layer 116 may be covered with the UBM layer 112. In particular, a UBM via 1121 of the UBM layer 112 may be formed by passing through the passivation layer 116 in a vertical direction, and the passivation layer 116 may completely cover the side surface of the UBM via 1121. A UBM pad 1123 of the UBM layer 112 may be disposed on the lower surface of the passivation layer 116 and may be in contact with the lower surface of the passivation layer 116. The passivation layer 116 may include, for example, an insulating material including silicon oxide, silicon nitride, phosphosilicate glass (PSG), borophosphosilicate glass (BPSG), fluorosilicate glass (FSG), or any combination thereof.

According to an embodiment, the conductive layer 114 may be arranged within the passivation layer 116, and the upper surface of the conductive layer 114 may be exposed from the upper surface of the passivation layer 116. The conductive layer 114 may be disposed below the first conductive post 132 and the second conductive post 134, and the upper surface of the conductive layer 114 may be bonded to a lower surface 132a of the first conductive post 132 and a lower surface 134a of the second conductive post 134. The conductive layer 114 may be conductive patterns spaced apart from each other in the first horizontal direction (the X direction) or the second horizontal direction (the Y direction). For example, FIG. 1B illustrates that the conductive layer 114 is patterns arranged at one vertical level, but in some embodiments, the conductive layer 114 may be multilayered conductive patterns arranged at different vertical levels within the passivation layer 116. The conductive layer 114 may be used to electrically connect different elements (e.g., the first conductive post 132 and the second conductive post 134 and the UBM layer 112) to each other. The conductive layer 114 may include, for example, a conductive material including copper (Cu), aluminum (Al), silver (Ag), gold (Au), tungsten (W), titanium (Ti), or any combination thereof.

According to an embodiment, the UBM layer 112 may include the UBM pad 1123 disposed on the lower surface of the passivation layer 116, and the UBM via 1121 passing through a portion of the passivation layer 116 and connecting the UBM pad 1123 to the conductive layer 114. The UBM via 1121 may have a truncated cone cup shape in which a portion of the central space is empty, but in some embodiments, the UBM via 1121 may have a truncated cone shape in which the central space is filled. The UBM pad 1123 may have an annular shape in which the central space is empty, but in some embodiments, the UBM pad 1123 may have a coin shape in which the central space is filled. The UBM layer 112 may be used to electrically connect different elements (e.g., the conductive layer 114 and an external connection terminal 190 to be described below) to each other. In addition, the UBM layer 112 may improve reliability of the semiconductor package 10 by suppressing occurrence of cracks in the external connection terminal 190 due to thermal shock between the external connection terminal 190 and the redistribution structure 110. The UBM layer 112 may include, for example, a conductive material including copper (Cu), aluminum (Al), silver (Ag), gold (Au), tungsten (W), titanium (Ti), or any combination thereof.

As illustrated in FIG. 1B, the external connection terminal 190 is not directly bonded to the first conductive post 132 and the second conductive post 134 surrounding the bridge chip 160. Instead, the redistribution structure 110 may be formed between the bridge chip 160 and the first conductive post 132 (and the second conductive post 134). When the redistribution structure 110 is formed between the first conductive post 132 (and the second conductive post 134) and the external connection terminal 190, the size of the line width of the conductive layer 114 is less than the size of the external connection terminal 190, and thus, a finer manufacturing process is possible. In addition, when the redistribution structure 110 is formed between the first conductive post 132 (and the second conductive post 134) and the external connection terminal 190, a greater number of the external connection terminal 190 may be disposed under the bridge chip 160 than when a plurality of the external connection terminals 190 is directly bonded to the first conductive post 132 and the second conductive post 134. When the semiconductor package 10 includes a greater number of the external connection terminal 190, more stable power supply is possible.

According to an embodiment, the semiconductor package 10 may further include the external connection terminal 190 disposed on the lower surface of the passivation layer 116. The external connection terminal 190 may be configured to electrically and physically connect the redistribution structure 110 to an external device. On the other hand, the external connection terminal 190 may have, for example, a flip-chip connection structure with a grid array, such as a solder ball, conductive bump, or pin grid array, a ball grid array, or a land grid array. The external connection terminal 190 may be electrically connected to the UBM layer 112 of the redistribution structure 110 and may be electrically connected to an external device, such as a module substrate or a system board.

According to an embodiment, the bridge chip 160 may be mounted on the upper surface of the redistribution structure 110. The entire lower surface of the bridge chip 160 may be in contact with the passivation layer 116. The bridge chip 160 may provide an electrical connection path between the first semiconductor chip 140 and the second semiconductor chip 150 disposed on the redistribution structure 110. Specifically, the first semiconductor chip 140 and the second semiconductor chip 150 may be electrically connected to each other through a bridge circuit 162 of the bridge chip 160. As illustrated in FIGS. 1A and 1B, the first semiconductor chip 140 and the second semiconductor chip 150 may overlap a portion of the periphery of the bridge chip 160 in the vertical direction (the Z direction).

The bridge chip 160 may include a bridge body 161, the bridge circuit 162, and a plurality of bridge chip pads. The bridge chip pads may include a first bridge chip pad 163a and a second bridge chip pad 163b spaced apart from the first bridge chip pad 163a in the first horizontal direction (the X direction). The bridge body 161 may be formed based on a substrate. The substrate may include a semiconductor material, for example, a Group IV semiconductor material, a Group III-V semiconductor material, a Group II-VI semiconductor material, or any combination thereof. The Group IV semiconductor material may include, for example, silicon (Si), germanium (Ge), or any combination thereof. The Group III-V semiconductor material may include, for example, gallium arsenide (GaAs), indium phosphate (InP), gallium phosphate (GaP), indium arsenide (InAs), indium antimony (InSb), indium gallium arsenide (InGaAs), or any combination thereof. The Group II-VI semiconductor material may include, for example, zinc telluride (ZnTe), cadmium sulfide (CdS), or any combination thereof. In addition, the substrate may include, in addition to the semiconductor material, glass or ceramic.

The bridge circuit 162 may be formed within the bridge body 161. The bridge circuit 162 may have a pitch corresponding to a fine pitch of chip pads (e.g., a first chip pad 142a, a second chip pad 142b, a third chip pad 152a, and a fourth chip pad 152b) of the first semiconductor chip 140 and the second semiconductor chip 150. Accordingly, a line and space (L/S) standard of the bridge circuit 162 may be 2 micrometers or less. The bridge circuit 162 may act as a bridge electrically connecting the first chip pad 142a and the second chip pad 142b of the first semiconductor chip 140 to the third chip pad 152a and the fourth chip pad 152b of the second semiconductor chip 150. The bridge circuit 162 may have a finer pitch than a pitch of the conductive layer 114. For example, the line width of the bridge circuit 162 may be less than the line width of the conductive layer 114.

The first bridge chip pad 163a and the second bridge chip pad 163b may be arranged within the bridge body 161, and the upper surfaces of the first bridge chip pad 163a and the second bridge chip pad 163b may be exposed from the upper surface of the bridge body 161. That is, the upper surfaces of the first bridge chip pad 163a and the second bridge chip pad 163b may be located on the same plane as the upper surface of the bridge body 161. The upper surface of the first bridge chip pad 163a may be physically and electrically connected to the first vertical connection conductor 172 to be described below. Specifically, the upper surface of the first bridge chip pad 163a may be bonded to the lower surface 172a of the first vertical connection conductor 172. In addition, the upper surface of the second bridge chip pad 163b may be physically and electrically connected to the second vertical connection conductor 174 to be described below. Specifically, the upper surface of the second bridge chip pad 163b may be bonded to the lower surface 174a of the second vertical connection conductor 174. That is, the first bridge chip pad 163a may provide a connection site between the first vertical connection conductor 172 and the bridge circuit 162, and the second bridge chip pad 163b may provide a connection site between the second vertical connection conductor 174 and the bridge circuit 162. The first bridge chip pad 163a and the second bridge chip pad 163b may each include, for example, a conductive material including copper (Cu), aluminum (Al), silver (Ag), gold (Au), tungsten (W), titanium (Ti), or any combination thereof.

According to an embodiment, the first conductive post 132 and the second conductive post 134 may be spaced apart from each other in the first horizontal direction (the X direction) with the bridge chip 160 therebetween within the first molding layer 136. A plurality of the first conductive posts 132 may be provided such as to vertically overlap with the first semiconductor chip 140, and a plurality of the second conductive posts 134 may be provided such as to vertically overlap with the second semiconductor chip 150. As illustrated in FIG. 1A, the plurality of the first conductive posts 132 may all overlap with the first semiconductor chip 140, and the plurality of the second conductive posts 134 may all overlap with the second semiconductor chip 150. The first molding layer 136 may cover the first conductive post 132, the second conductive post 134, the bridge chip 160, the first vertical connection conductor 172, and the second vertical connection conductor 174 between the first semiconductor chip 140 (and the second semiconductor chip 150) and the redistribution structure 110. The first conductive post 132 and the second conductive post 134 may pass through the first molding layer 136 in the vertical direction (the Z direction), and the length of each of the first conductive post 132 and the second conductive post 134 in the vertical direction (the Z direction) may be equal to the length of the first molding layer 136 in the vertical direction (the Z direction).

According to an embodiment, a plurality of the first conductive posts 132 and a plurality of the second conductive posts 134 may be arranged between the first semiconductor chip 140 (and the second semiconductor chip 150) and the redistribution structure 110 within the first molding layer 136. Each first conductive post 132 may have a lower surface 132a and an upper surface 132b opposite to the lower surface 132a in the vertical direction (the Z direction). Similarly, each second conductive post 134 may have a lower surface 134a and an upper surface 134b opposite to the lower surface 134a in the vertical direction (the Z direction). The lower surface 132a of the first conductive post 132 and the lower surface 134a of the second conductive post 134 may be located on the same plane as a plane of the lower surface of the first molding layer 136, and the upper surface 132b of the first conductive post 132 and the upper surface 134b of the second conductive post 134 may be located on the same plane as a plane of the upper surface of the first molding layer 136. In addition, as illustrated in FIGS. 1A and 1B, a distance d2 between a pair of conductive posts arranged adjacent to each other among the first conductive post 132 and the second conductive post 134 in the first horizontal direction (the X direction) may be constant. However, in some embodiments, the distances between a pair of conductive posts arranged adjacent to each other among the first conductive post 132 and the second conductive post 134 in the first horizontal direction (the X direction) may be different from each other.

The first conductive post 132 and the second conductive post 134 may each have a single cylindrical shape. In this case, the diameters of the first conductive post 132 and the second conductive post 134 may be constantly maintained in the vertical direction (the Z direction). However, according to another embodiment, the first conductive post 132 and the second conductive post 134 may each have a tapered shape in which the diameter thereof gradually increases or decreases in the vertical direction (the Z direction).

Each first conductive post 132 may be in direct contact with the conductive layer 114 exposed from the upper surface of the passivation layer 116. Specifically, the lower surface 132a of each first conductive post 132 may be bonded to the upper surface of the conductive layer 114. In addition, each first conductive post 132 may be in direct contact with a first solder bump 144a of the first semiconductor chip 140. Specifically, the upper surface 132b of each first conductive post 132 may be bonded to a respective first solder bump 144a of the first semiconductor chip 140. Each first conductive post 132 may provide an electrical connection path between the redistribution structure 110 and the first semiconductor chip 140.

Each second conductive post 134 may be in direct contact with the conductive layer 114 exposed from the upper surface of the passivation layer 116. Specifically, the lower surface 134a of each second conductive post 134 may be bonded to the upper surface of the conductive layer 114. In addition, each second conductive posts 134 may be in direct contact with a third solder bump 154a of the second semiconductor chip 150. Specifically, the upper surface 134b of each second conductive post 134 may be bonded to a respective third solder bump 154a of the second semiconductor chip 150. Each second conductive post 134 may provide an electrical connection path between the redistribution structure 110 and the second semiconductor chip 150. The first conductive post 132 and the second conductive post 134 may each include, for example, a conductive material including copper (Cu), aluminum (Al), silver (Ag), gold (Au), tungsten (W), titanium (Ti), or any combination thereof.

According to an embodiment, the first vertical connection conductor 172 (and the second vertical connection conductor 174) may be arranged between the first semiconductor chip 140 (and the second semiconductor chip 150) and the bridge chip 160 within the first molding layer 136. Each first vertical connection conductor 172 may have a lower surface 172a and an upper surface 172b opposite to the lower surface 172a in the vertical direction (the Z direction). Similarly, the second vertical connection conductors 174 may each have a lower surface 174a and an upper surface 174b opposite to the lower surface 174a in the vertical direction (the Z direction). In this case, the upper surface 172b of the first vertical connection conductor 172 may be bonded to the second solder bump 144b of the first semiconductor chip 140, and the lower surface 172a of the first vertical connection conductor 172 may be bonded to the first bridge chip pad 163a. In addition, the upper surface 174b of the second vertical connection conductor 174 may be bonded to the fourth solder bump 154b of the second semiconductor chip 150, and the lower surface 174a of the second vertical connection conductor 174 may be bonded to the second bridge chip pad 163b.

As illustrated in FIGS. 1A and 1B, a distance dl in the first horizontal direction between a first conductive post 132 arranged closest to the periphery of the bridge chip 160 among the first conductive posts 132 and a vertical connection conductor arranged closest to the periphery of the bridge chip 160 among the first vertical connection conductors 172 may be greater than the distance d2 in the first horizontal direction between a pair of conductive posts arranged to each other among the first conductive posts.

The first vertical connection conductor 172 and the second vertical connection conductor 174 may each have a single cylindrical shape. In this case, the diameters of the first vertical connection conductor 172 and the second vertical connection conductor 174 may be constantly maintained in the vertical direction (the Z direction). However, according to another embodiment, the first vertical connection conductor 172 and the second vertical connection conductor 174 may each have a tapered shape in which the diameter thereof gradually increases or decreases in the vertical direction (the Z direction).

According to an embodiment, the first molding layer 136 may cover the side surfaces of the first conductive post 132 and the first vertical connection conductor 172 between the redistribution structure 110 and the first semiconductor chip 140, and the side surfaces of the second conductive post 134 and the second vertical connection conductor 174 between the redistribution structure 110 and the second semiconductor chip 150. In addition, the first molding layer 136 may completely seal the bridge chip 160. The first molding layer 136 may include, for example, thermosetting resin, thermoplastic resin, ultraviolet (UV) curable resin, or any combination thereof. The first molding layer 136 may include, for example, epoxy resin, silicone resin, or any combination thereof. The first molding layer 136 may include, for example, an epoxy mold compound (EMC).

According to an embodiment, the semiconductor package 10 may include semiconductor chips mounted on the first molding layer 136 and the bridge chip 160, and the semiconductor chips may respectively include a first set of chip pads and solder bumps and a second set of chip pads and solder bumps. In this case, the semiconductor chips may include the first semiconductor chip 140 and the second semiconductor chip 150 spaced apart from the first semiconductor chip 140 in the first horizontal direction (the X direction).

The first semiconductor chip 140 may include the first chip pad 142a, the second chip pad 142b, the first solder bump 144a, the second solder bump 144b, and a first chip body 146. The second semiconductor chip 150 may include the third chip pad 152a, the fourth chip pad 152b, the third solder bump 154a, the fourth solder bump 154b, and a second chip body 156.

The first chip body 146 and the second chip body 156 may each include an integrated circuit. The integrated circuit may be any type of integrated circuit including a memory circuit, a logic circuit, or any combination thereof. The memory circuit may be, for example, a dynamic random access memory (DRAM) circuit, a static random access memory (SRAM) circuit, a flash memory circuit, an electrically erasable and programmable read-only memory (EEPROM) circuit, a phase-change random access memory (PRAM) circuit, a magnetic random access memory (MRAM) circuit, a resistive random access memory (RRAM) circuit, or any combination thereof. The logic circuit may be, for example, a central processing unit (CPU) circuit, a graphic processing unit (GPU) circuit, a controller circuit, an application specific integrated circuit (ASIC) circuit, an application processor (AP) circuit, or any combination thereof.

The integrated circuit may include a substrate. The substrate may include a semiconductor material, for example, a Group IV semiconductor material, a Group III-V semiconductor material, a Group II-VI semiconductor material, or any combination thereof. The Group IV semiconductor material may include, for example, silicon (Si), germanium (Ge), or any combination thereof. The Group III-V semiconductor material may include, for example, gallium arsenide (GaAs), indium phosphate (InP), gallium phosphate (GaP), indium arsenide (InAs), indium antimony (InSb), indium gallium arsenide (InGaAs), or any combination thereof. The Group II-VI semiconductor material may include, for example, zinc telluride (ZnTe), cadmium sulfide (CdS), or any combination thereof.

The first chip pad 142a and the second chip pad 142b may be disposed on the lower surface of the first chip body 146 along the lower surface of the first chip body 146. The first chip pad 142a may be in contact with the first solder bump 144a, and the second chip pad 142b may be in contact with the second solder bump 144b. In this case, the first chip pad 142a and the first solder bump 144a may provide an electrical connection path between the first semiconductor chip 140 and the first vertical connection conductor 172. In addition, the second chip pad 142b and the second solder bump 144b may provide an electrical connection path between the first semiconductor chip 140 and the bridge chip 160.

The third chip pad 152a and the fourth chip pad 152b may be disposed on the lower surface of the second chip body 156 along the lower surface of the second chip body 156. The third chip pad 152a may be in contact with the third solder bump 154a, and the fourth chip pad 152b may be in contact with the fourth solder bump 154b. In this case, the third chip pad 152a and the third solder bump 154a may provide an electrical connection path between the second semiconductor chip 150 and the second conductive post 134. In addition, the fourth chip pad 152b and the fourth solder bump 154b may provide an electrical connection path between the second semiconductor chip 150 and the bridge chip 160.

The first chip pad 142a, the second chip pad 142b, the third chip pad 152a, and the fourth chip pad 152b may each include, for example, a conductive material including copper (Cu), aluminum (Al), silver (Ag), gold (Au), tungsten (W), titanium (Ti), or any combination thereof. In addition, the first solder bump 144a, the second solder bump 144b, the third solder bump 154a, and the fourth solder bump 154b may each include, for example, a solder ball.

The first solder bump 144a and the third solder bump 154a may enable self-alignment between the first conductive post 132 and the second conductive post 134 corresponding thereto and the first chip pad 142a and the third chip pad 152a corresponding thereto, respectively. That is, the first solder bump 144a may enable alignment of the central portion of the first conductive post 132 and the central portion of the first chip pad 142a with a first center line L1 without error. The first center line L1 may be defined as an imaginary line of the vertical direction (the Z direction) where the central portion of the first conductive post 132 overlaps with the central portion of the first chip pad 142a. In addition, the third solder bump 154a may enable alignment of the central portion of the second conductive post 134 and the central portion of the first chip pad 142a with a fourth center line LA without error. The fourth center line L4 may be defined as an imaginary line of the vertical direction (the Z direction) where the central portion of the second conductive post 134 overlaps with the central portion of the fourth chip pad 152b.

A center line passing through the center of the first chip pad 142a may be located within 10 micrometers to 100 micrometers in the first horizontal direction (the X direction) from the center line passing through the center of the first conductive post 132. A center line passing through the center of the second chip pad 142b may be located within 10 micrometers to 100 micrometers in the first horizontal direction (the X direction) from the center line passing through the center of the first vertical connection conductor 172. A center line passing through the center of the third chip pad 152a may be located within 10 micrometers to 100 micrometers in the first horizontal direction (the X direction) from the center line passing through the center of the second conductive post 134. A center line passing through the center of the fourth chip pad 152b may be located within 10 micrometers to 100 micrometers in the first horizontal direction (the X direction) from the center line passing through the center the second vertical connection conductor 174.

The second solder bump 144b and the fourth solder bump 154b may enable self-alignment between the first vertical connection conductor 172 and the second vertical connection conductor 174 corresponding thereto and the second chip pad 142b and the fourth chip pad 152b corresponding thereto, respectively. That is, the second solder bump 144b may enable alignment of the central portion of the first vertical connection conductor 172 and the central portion of the second chip pad 142b with the second center line L2 without error. The second center line L2 may be defined as an imaginary line of the vertical direction (the Z direction) where the central portion of the first vertical connection conductor 172 overlaps with the central portion of the second chip pad 142b. In addition, the fourth solder bump 154b may enable alignment of the central portion of the second vertical connection conductor 174 and the central portion of the fourth chip pad 152b with a third center line L3 without error. The third center line L3 may be defined as an imaginary line of the vertical direction (the Z direction) where the central portion of the second vertical connection conductor 174 overlaps with the central portion of the fourth chip pad 152b.

According to an embodiment, the semiconductor package 10 may further include an underfill material 182 disposed on the first molding layer 136 and filling a portion of a space between the first molding layer 136 and the first semiconductor chip 140 (and the second semiconductor chip 150), and a second molding layer 184 disposed on the first molding layer 136 and sealing the first semiconductor chip 140 and the second semiconductor chip 150. The underfill material 182 may completely cover the first chip pad 142a, the second chip pad 142b, the third chip pad 152a, the fourth chip pad 152b, the first solder bump 144a, the second solder bump 144b, the third solder bump 154a, and the fourth solder bump 154b. In addition, the underfill material 182 may partially cover the side surfaces of the first chip body 146 of the first semiconductor chip 140 and the second chip body 156 of the second semiconductor chip 150. In some embodiments, the underfill material 182 may completely cover the side surfaces of the first chip body 146 and the second chip body 156. The underfill material 182 may include an inclined outer surface. The underfill material 182 may include epoxy resin or two or more types of silicone hybrid material.

According to an embodiment, the second molding layer 184 may be disposed on the first molding layer 136 and the underfill material 182 and cover portions of the side surfaces of the first chip body 146, the second chip body 156, and the underfill material 182. The second molding layer 184 may include, for example, thermosetting resin, thermoplastic resin, UV curable resin, or any combination thereof. The second molding layer 184 may include, for example, epoxy resin, silicone resin, or any combination thereof. The second molding layer 184 may include, for example, an EMC. However, an insulating material included in the second molding layer 184 may be different from an insulating material included in the first molding layer 136.

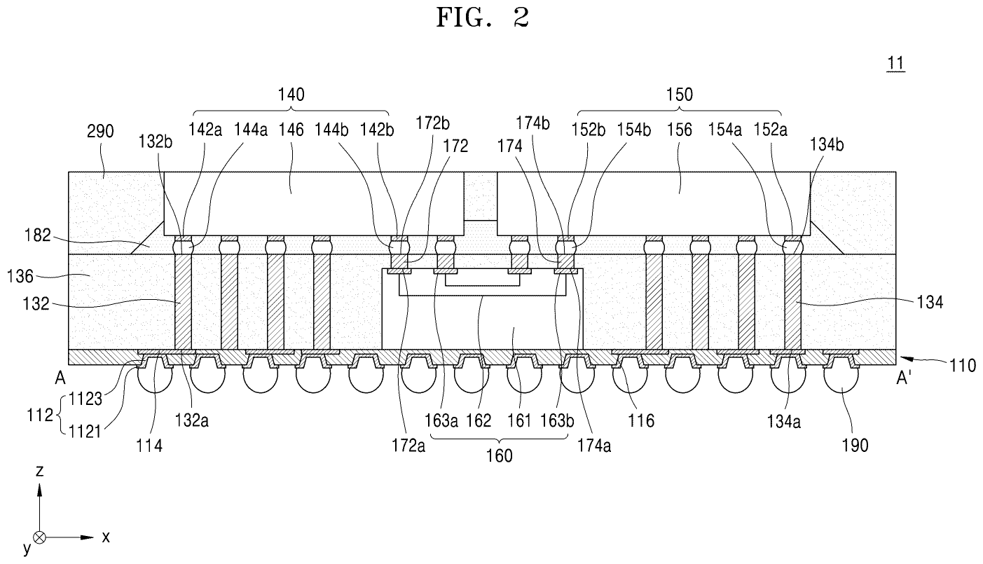

FIGS. 2 to 6 are cross-sectional views of semiconductor packages according to embodiments. FIGS. 2 to 6 are cross-sectional views of the semiconductor packages corresponding to FIG. 1B.

Referring to FIG. 2, the semiconductor package 11 illustrated in FIG. 2 is substantially the same as or similar to the semiconductor package 10 illustrated in FIG. 1B, except that an insulating material constituting a second molding layer 290 is the same as an insulating material constituting a first molding layer 136. Therefore, repeated descriptions of the elements as provided above with reference to FIG. 1B are omitted.

The first molding layer 136 and the second molding layer 290 illustrated in FIG. 2 may each include, for example, one of thermosetting resin, thermoplastic resin, UV curable resin, or any combination thereof. The second molding layer 290 may include, for example, one of epoxy resin, silicone resin, or any combination thereof. The second molding layer 184 may include, for example, an EMC. However, the insulating material included in the second molding layer 290 may be the same as the insulating material included in the first molding layer 136. When the insulating material included in the first molding layer 136 is the same as the insulating material included in the second molding layer 290, warpage may be decreased under conditions of a specific pressure and a specific temperature.

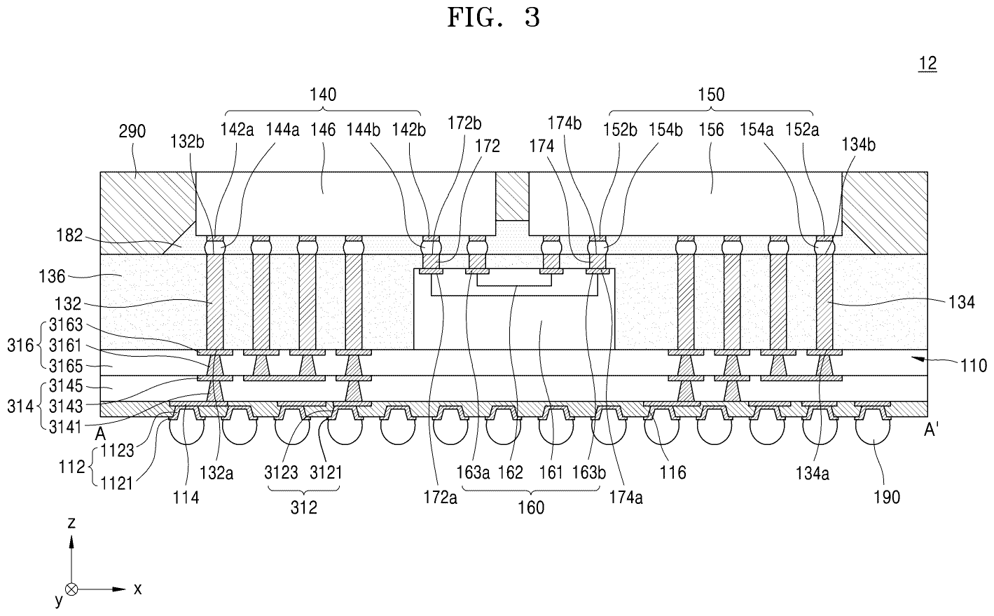

Referring to FIG. 3, a semiconductor package 12 illustrated in FIG. 3 is substantially the same as or similar to the semiconductor package 12 illustrated in FIG. 1B, except for a structure of a redistribution structure 310. Therefore, repeated descriptions of the elements as provided above with reference to FIG. 1B are omitted.

The redistribution structure 310 may include a first redistribution pattern layer 314 and a second redistribution pattern layer 316 stacked on a passivation layer 116 in the vertical direction (the Z direction). The first redistribution pattern layer 314 may include first redistribution vias 3141, first redistribution conductive layers 3143, and a first redistribution insulating layer 3145. The first redistribution conductive layers 3143 may extend in the first horizontal direction (the X direction) and/or the second horizontal direction (the Y direction) and may be arranged on the same vertical level. The first redistribution conductive layers 3143 may be disposed under the upper surface of the first redistribution insulating layer 3145. For example, the first redistribution conductive layers 3143 may be line patterns extending in a line shape along the upper surface of the first redistribution insulating layer 3145. The first redistribution vias 3141 may pass through the first redistribution insulating layer 3145 and extend in the vertical direction (the Z direction). The first redistribution vias 3141 may electrically connect the first redistribution conductive layers 3143 and the conductive layer 114, which are arranged at different vertical levels, to each other. The first redistribution vias 3141 and the first redistribution conductive layers 3143 may be buried in the first redistribution insulating layer 3145. In this case, the lower surface of the first redistribution insulating layer 3145 may be located on the same plane as a plane of the lower surfaces of the first redistribution vias 3141, and the upper surface of the first redistribution insulating layer 3145 may be located on the same plane as a plane of the upper surfaces of the first redistribution conductive layers 3143.

Similarly, the second redistribution pattern layer 316 may include second redistribution vias 3161, second redistribution conductive layers 3163, and a second redistribution insulating layer 3165. The second redistribution conductive layers 3163 may extend in the first horizontal direction (the X direction) and/or the second horizontal direction (the Y direction) and may be arranged on the same vertical level. The second redistribution conductive layers 3163 may be disposed under the upper surface of the second redistribution insulating layer 3165. For example, the second redistribution conductive layers 3163 may be line patterns extending in a line shape along the upper surface of the second redistribution insulating layer 3165. The second redistribution vias 3161 may pass through the second redistribution insulating layer 3165 and extend in the vertical direction (the Z direction). The second redistribution vias 3161 may electrically connect the first redistribution conductive layers 3143 and the second redistribution conductive layers 3163, which are arranged at different vertical levels, to each other. The second redistribution vias 3161 and the second redistribution conductive layers 3163 may be buried in second redistribution insulating layer 3165. In this case, the lower surface of the second redistribution insulating layer 3165 may be located on the same plane as a plane of the lower surfaces of the second redistribution vias 3161, and the upper surface of the second redistribution insulating layer 3165 may be located on the same plane as a plane of the upper surfaces of the second redistribution conductive layers 3163 and/or the lower surfaces of the first conductive post 132 and the second conductive post 134.

The first redistribution vias 3141, the second redistribution vias 3161, the first redistribution conductive layers 3143, and the second redistribution conductive layers 3163 may each include, for example, a conductive material including copper (Cu), aluminum (Al), silver (Ag), gold (Au), tungsten (W), titanium (Ti), or any combination thereof. The first redistribution insulating layer 3145 and the second redistribution insulating layer 3165 may each include insulating polymer, epoxy, or any combination thereof. For example, the first redistribution insulating layer 3145 and the second redistribution insulating layer 3165 may each include polyimide (PI) or photosensitive polyimide (PSPI).

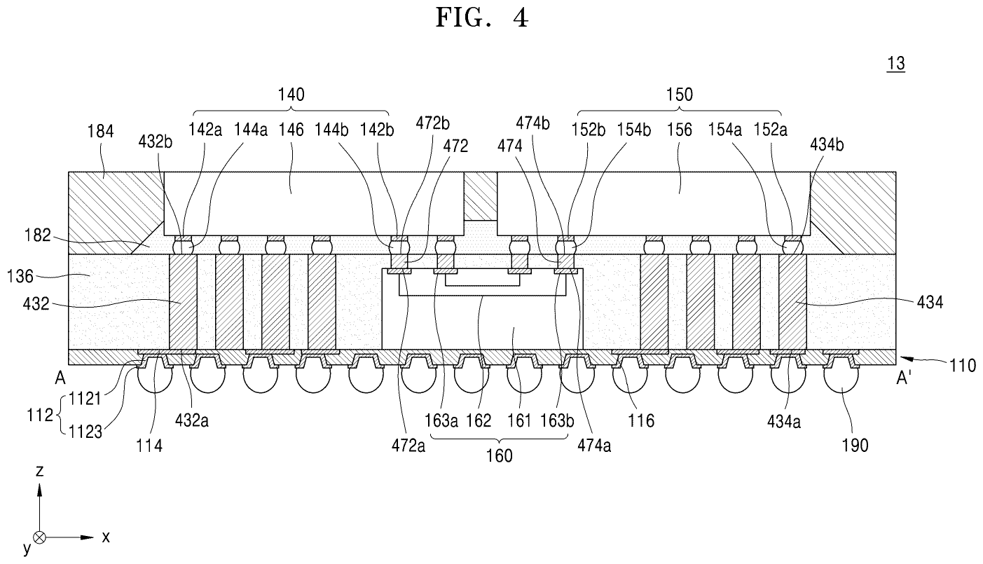

Referring to FIG. 4, a semiconductor package 13 illustrated in FIG. 4 is substantially the same as or similar to the semiconductor package 10 illustrated in FIG. 1B, except that the diameter of each of a plurality of the first conductive posts 432 and the plurality of the second conductive posts 434 is different from the diameter of each of a plurality of the first vertical connection conductors 472 and the plurality of the second vertical connection conductors 474, Therefore, repeated descriptions of the elements as provided above with reference to FIG. 1B are omitted.

As illustrated in FIG. 4, the diameter of each first conductive post 432 and each second conductive post 434 providing an electrical connection path between a plurality of semiconductor chips (e.g., a first semiconductor chip 140 and a second semiconductor chip 150) and a redistribution structure 110 may be greater than the diameter of each of the first vertical connection conductor 472 and each of the second vertical connection conductor 474 providing an electrical connection path between the first semiconductor chip 140 (and the second semiconductor chip 150) and a bridge chip 160. Each first vertical connection conductor 472 and second vertical connection conductor 474 may each have a single cylindrical shape. Accordingly, when the diameter of each of the first vertical connection conductor 472 and the second vertical connection conductor 474 increases, resistance may be further reduced, and thus, transmission of electrical signals may be further facilitated.

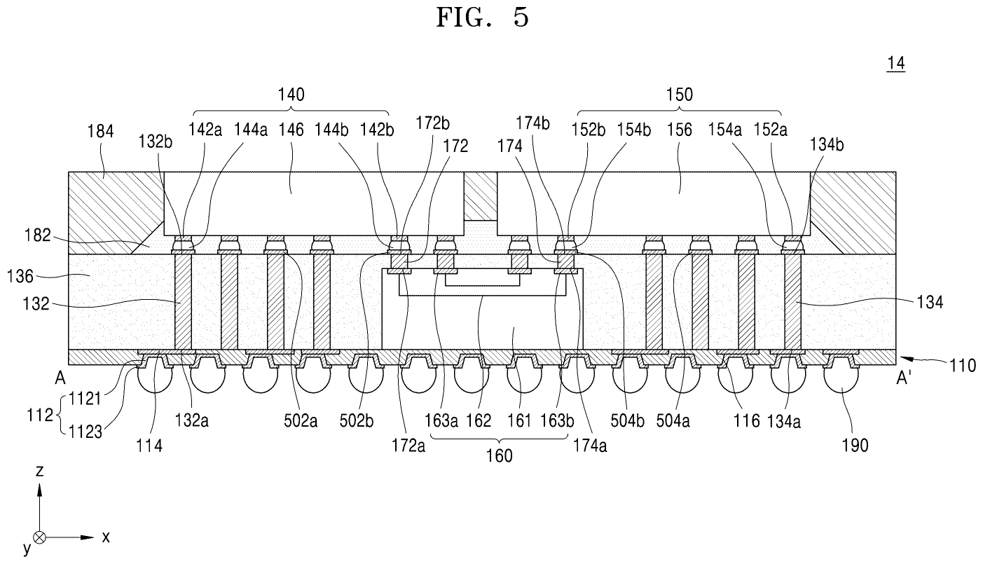

Referring to FIG. 5, a semiconductor package 14 illustrated in FIG. 5 is substantially the same as or similar to the semiconductor package 10 illustrated in FIG. 1B, except that a plurality of first conductive pads 502a and a plurality of third conductive pads 504a are further included between a plurality of conductive posts (e.g., the first conductive post 132 and the second conductive post 134) and solder bumps (e.g., the first solder bump 144a and the third solder bump 154a), and a plurality of second conductive pads 502b and a plurality of fourth conductive pads 504b are further included between a plurality of vertical connection conductors (e.g., the first vertical connection conductor 172 and the second vertical connection conductor 174) and solder bumps (e.g., the second solder bump 144b and the fourth solder bump 154b). Therefore, repeated descriptions of the elements as provided above with reference to FIG. 1B are omitted.

Specifically, the conductive pads may include the first conductive pad 502a, second conductive pad 502b, the third conductive pad 504a, and the fourth conductive pad 504b. The first conductive pad 502a may be arranged between the first conductive post 132 and the first solder bump 144a, and may be bonded to the first conductive post 132 and the first solder bump 144. The second conductive pad 502b may be arranged between the first vertical connection conductor 172 and the second solder bump 144b, and may be bonded to the first vertical connection conductor 172 and the second solder bump 144b. The third conductive pad 504a may be arranged between the second conductive post 134 and the third solder bump 154a, and may be bonded to the second conductive post 134 and the third solder bump 154a. The fourth conductive pad 504b may be arranged between the second vertical connection conductor 174 and the fourth solder bump 154b, and may be bonded to the second vertical connection conductor 174 and the fourth solder bump 154b. When the semiconductor package 14 further includes the first conductive pad 502a, the second conductive pad 502b, the third conductive pad 504a, and the fourth conductive pad 504b, the first solder bump 144a, the second solder bump 144b, the third solder bump 154a, and the fourth solder bump 154b may be more easily aligned and bonded to the first conductive post 132, the second conductive post 134, the first vertical connection conductor 172, and the second vertical connection conductor 174.

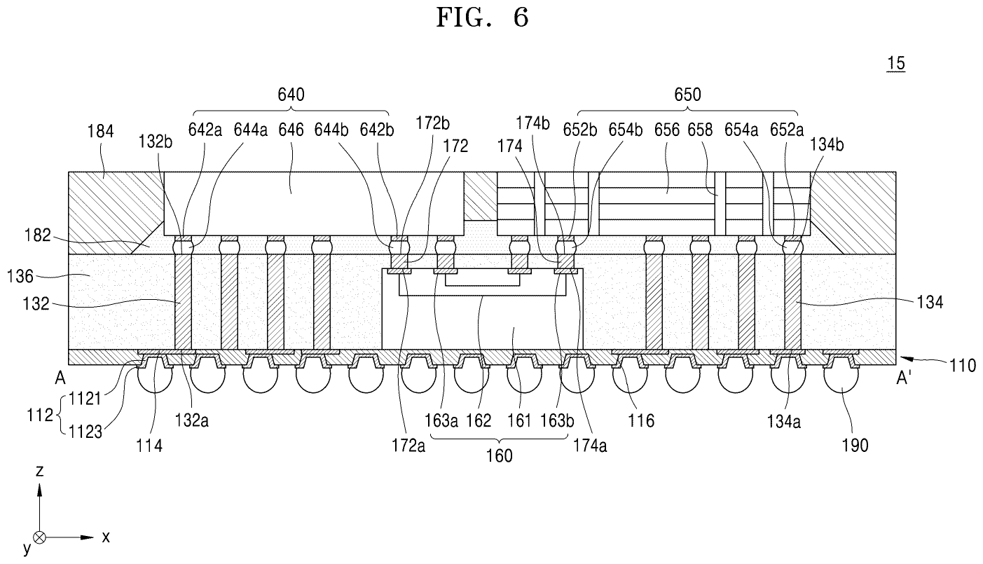

Referring to FIG. 6, a semiconductor package 15 illustrated in FIG. 6 is substantially the same as or similar to the semiconductor package 10 illustrated in FIG. 1B, except that a second semiconductor chip 650 includes a high bandwidth memory (HBM) chip. Therefore, repeatede descriptions of the elements as provided above with reference to FIG. 1B are omitted.

A plurality of semiconductor chips may include a first semiconductor chip 640 and the second semiconductor chip 650 spaced apart from the first semiconductor chip 640 in the first horizontal direction (the X direction). The first semiconductor chip 640 may include a first chip pad 642a, a second chip pad 642b, a first solder bump 644a, a second solder bump 644b, and a first chip body 646. Because the first semiconductor chip 640 illustrated in FIG. 6 is substantially the same as the first semiconductor chip 140 illustrated in FIG. 1B, repeated description thereof is omitted.

The second semiconductor chip 650 may include a third chip pad 652a, a fourth chip pad 652b, a third solder bump 654a, a fourth solder bump 654b, a plurality of stacked chips 656, and through silicon vias 658. The stacked chips 656 may be connected to each other through the through silicon vias 658. The through silicon vias 658 may pass through the stacked chips 656. The through silicon vias 658 may each include at least one of metal or metal nitride. For example, the through silicon vias 176 may each include at least one of titanium (Ti), tantalum (Ta), aluminum (Al), gold (Au), copper (Cu), nickel (Ni), tungsten (W), titanium nitride (TiN), or tantalum nitride (TaN). The stacked chips 656 may each be a logic semiconductor chip or a memory semiconductor chip. However, all of the stacked chips 656 may not be of the same type. For example, the lowermost chip among the stacked chips 656 may be a logic semiconductor chip, and the other chips may be memory semiconductor chips. The logic semiconductor chip may be, for example, an AP, a CPU, or a controller. The memory semiconductor circuit may be, for example, DRAM, SRAM, PRAM, MRAM, RRAM, flash memory, or EEPROM.

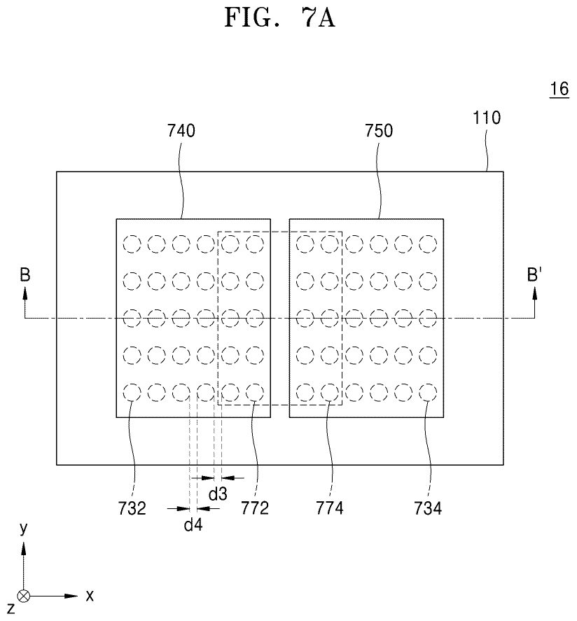

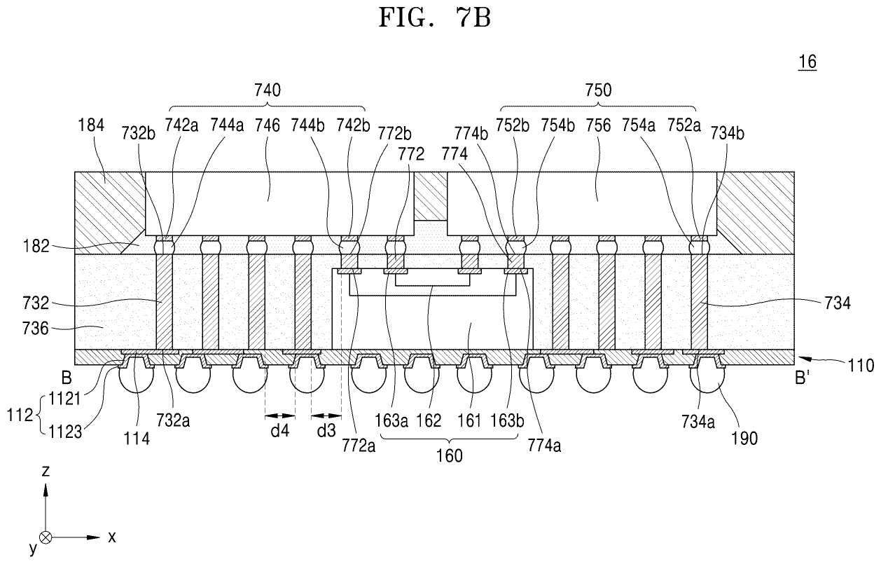

FIG. 7A is a plan view of a semiconductor package 16 according to an embodiment, and FIG. 7B is a cross-sectional view of the semiconductor package 16 taken along line B-B′ of FIG. 7A.

Referring to FIGS. 7A and 7B, the semiconductor package 16 illustrated in FIGS. 7A and 7B is substantially the same as or similar to the semiconductor package 10 illustrated in FIG. 1B, except that a distance d3 in the first horizontal direction (the X direction) between a conductive post arranged closest to a periphery of a bridge chip 160 among a plurality of conductive posts 732 and 734 is equal to a distance d4 in the first horizontal direction (the X direction) between a pair of conductive posts arranged adjacent to each other among the conductive posts 732 and 734. Therefore, repeated descriptions of the elements as provided above with reference to FIG. 1B are omitted.

When the distance d3 in the first horizontal direction (the X direction) between the conductive post arranged closest to the periphery of the bridge chip 160 among the conductive posts 732 and 734 is equal to the distance d4 in the first horizontal direction (the X direction) between the pair of conductive posts arranged adjacent to each other among the conductive posts 732 and 734, the overall size of the semiconductor package 16 may be further reduced and the manufacturing cost of the semiconductor package 16 may be reduced.

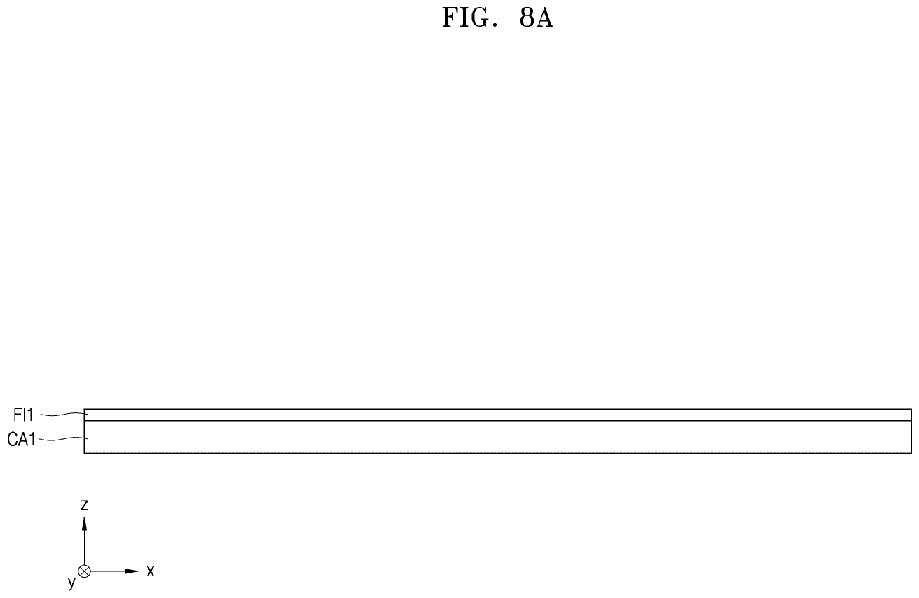

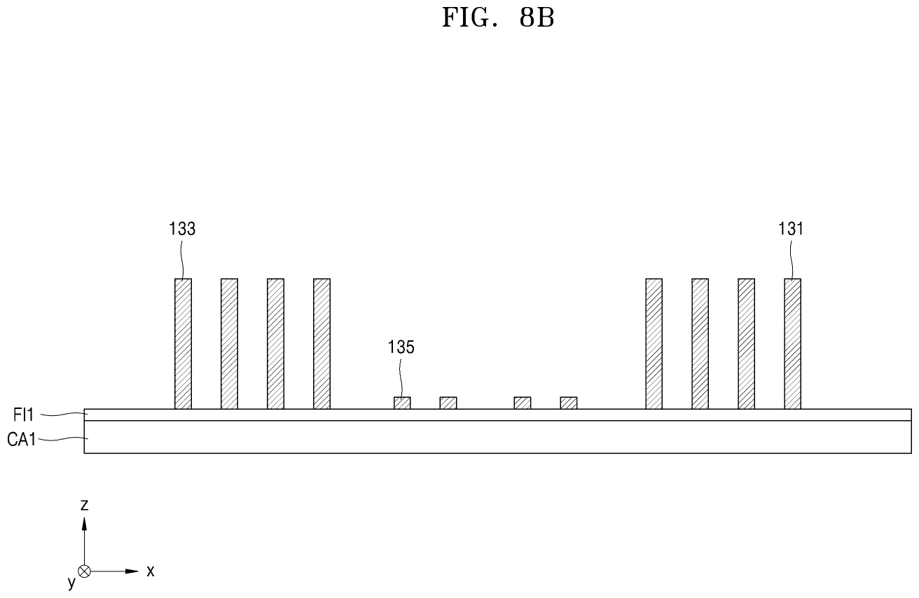

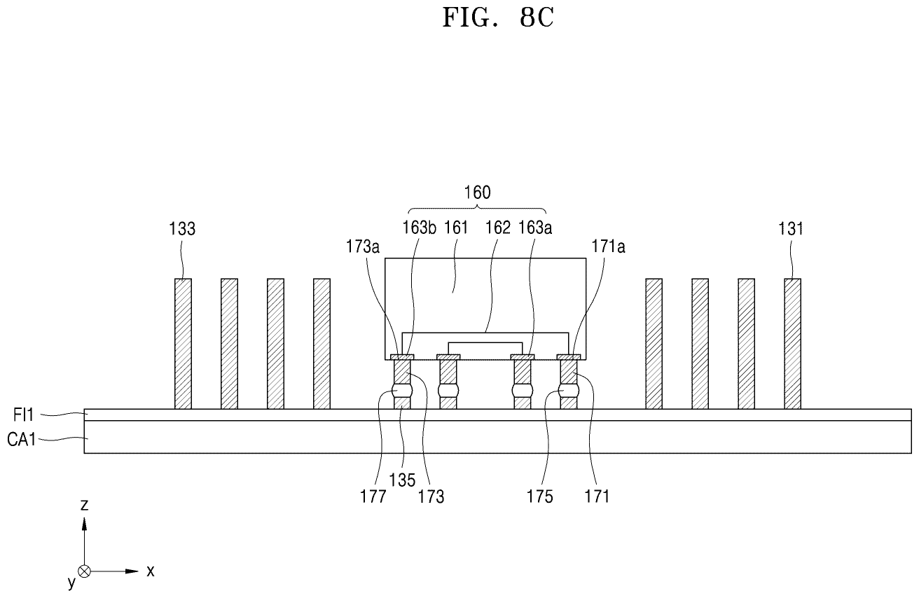

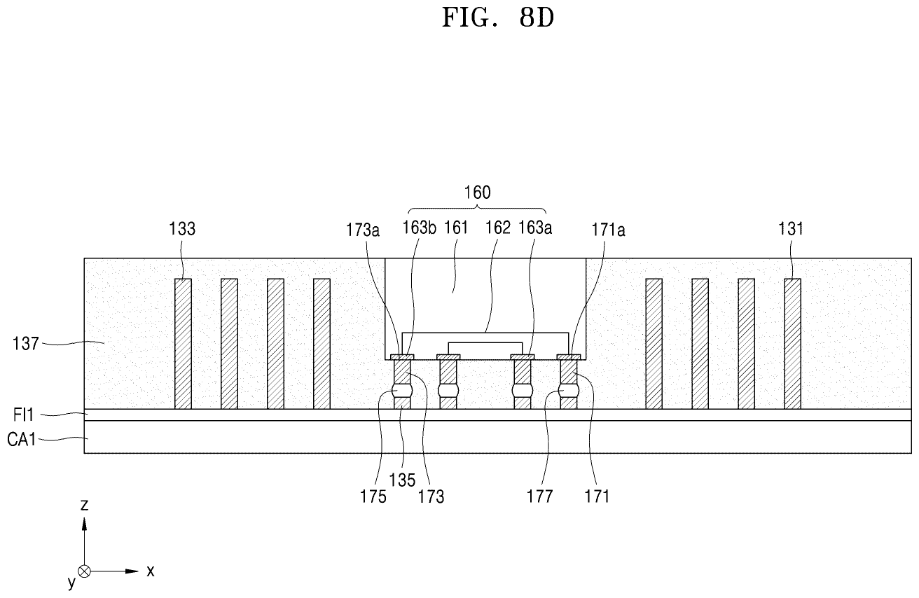

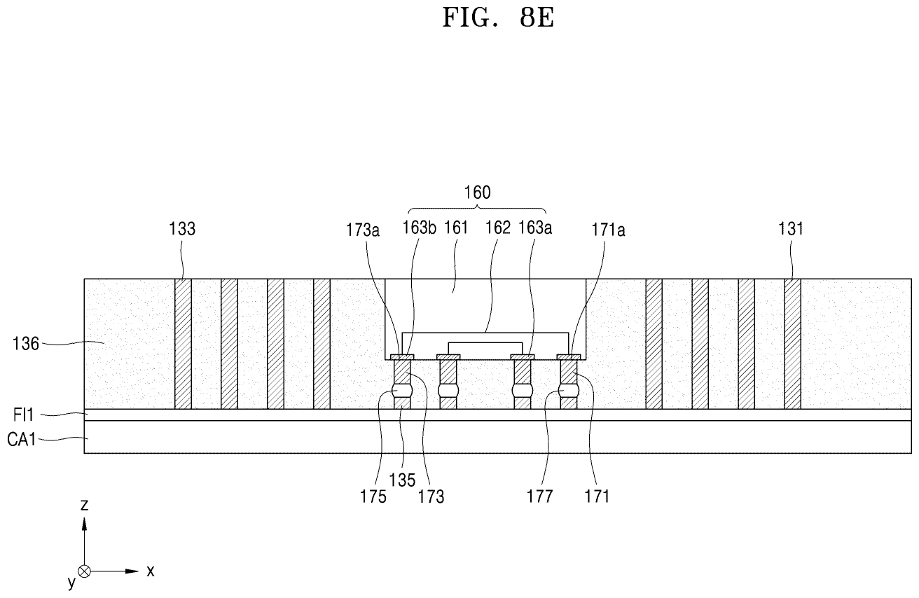

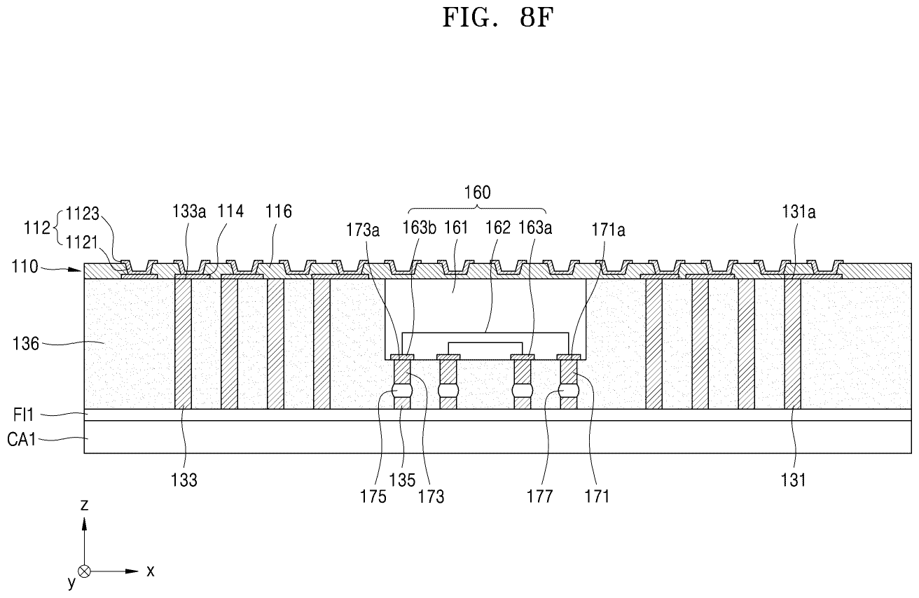

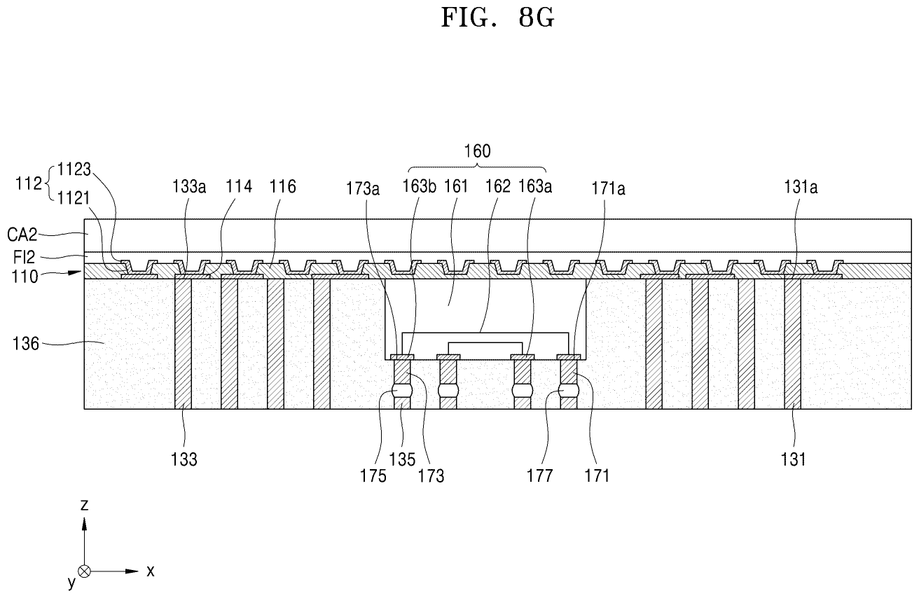

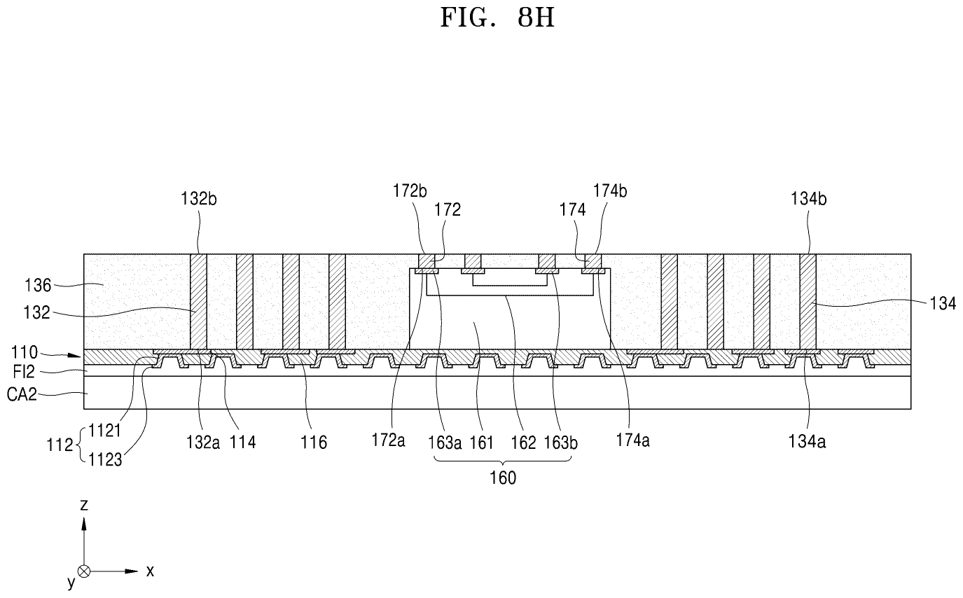

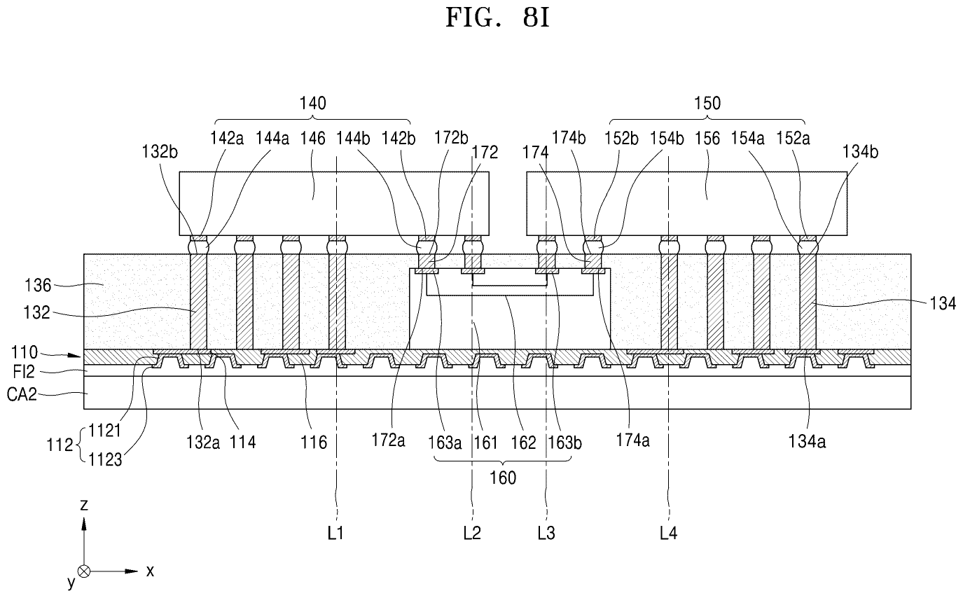

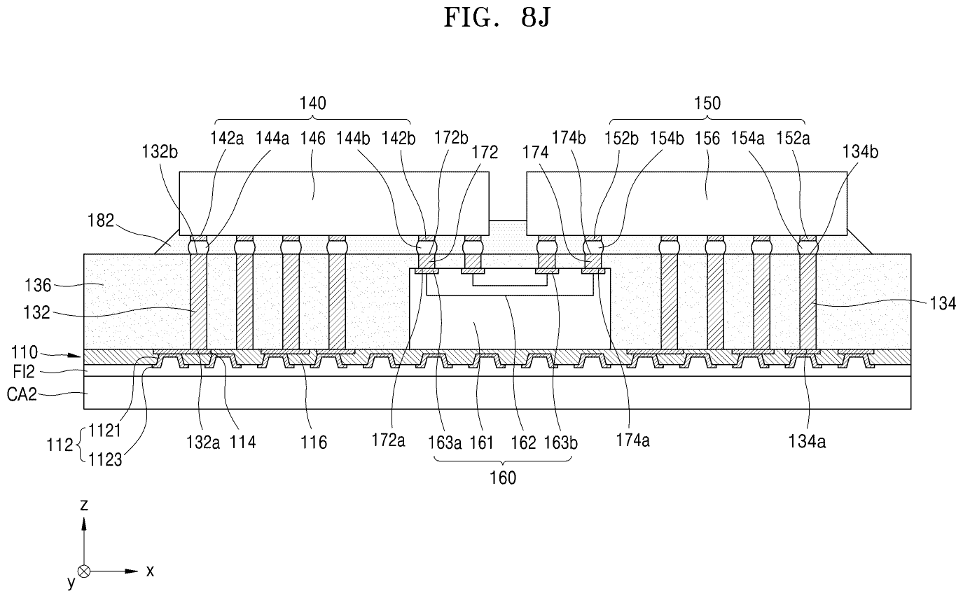

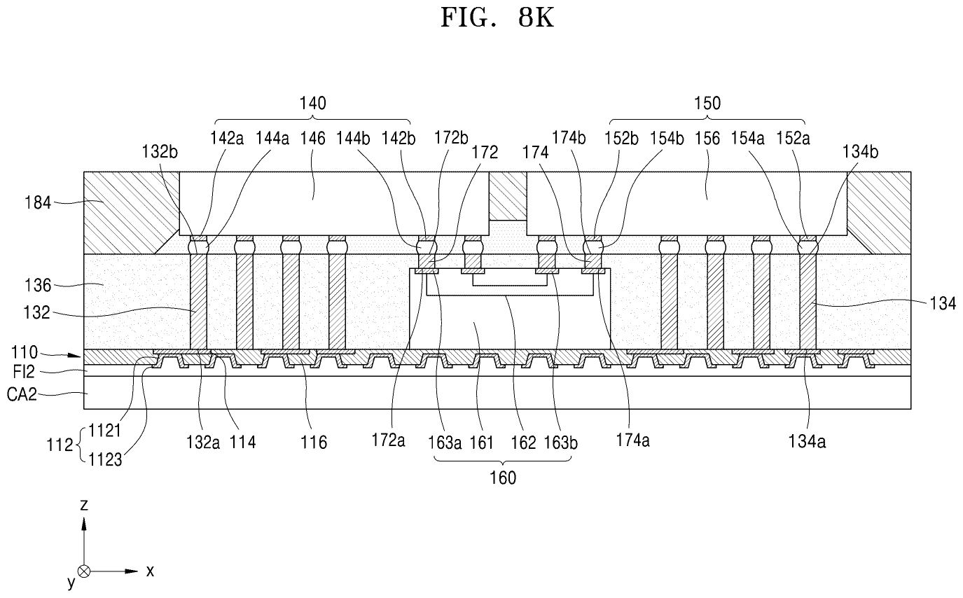

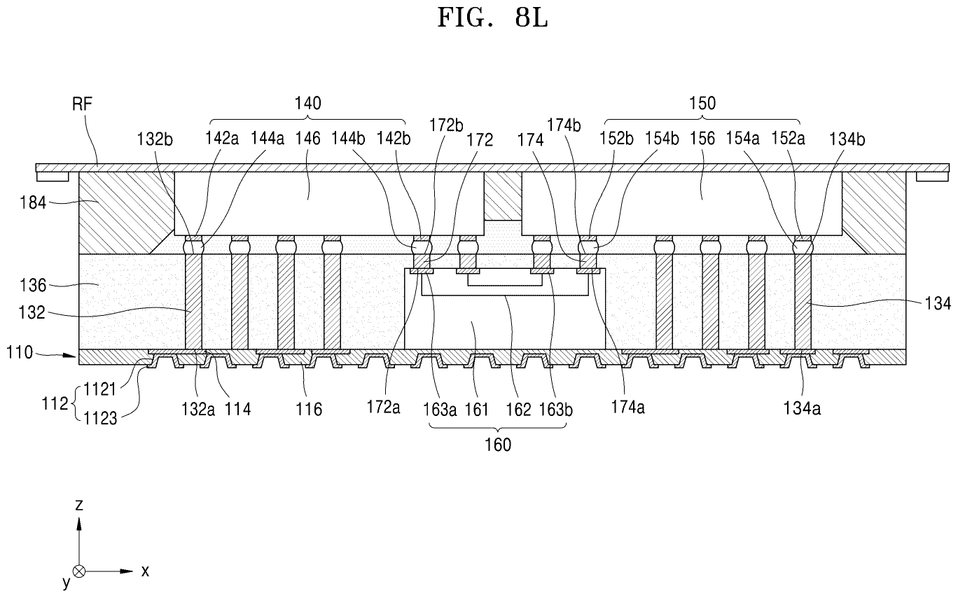

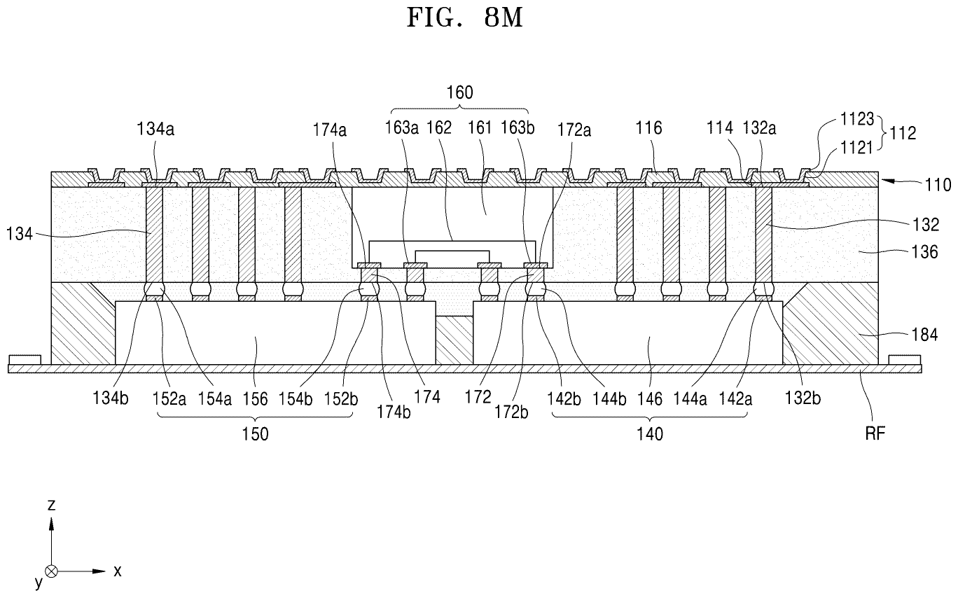

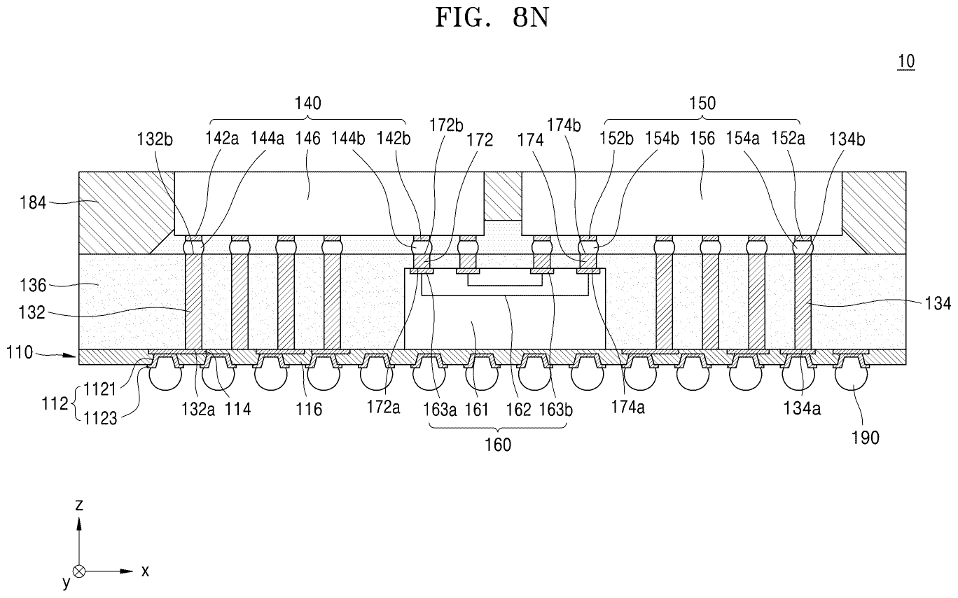

FIGS. 8A to 8N are cross-sectional views sequentially illustrating a method of manufacturing the semiconductor package illustrated in FIGS. 1A and 1B.

Referring to FIG. 8A, a first adhesive film FI1 may be bonded to a first carrier substrate CA1. The first adhesive film FI1 may include any material capable of fixing a plurality of conductive members (e.g., first conductive members 131, second conductive members 133, and third conductive members 135 of FIG. 8B). The first adhesive film FI1 may be, for example, a heat-curable adhesive tape, an adhesive force of which is weakened by heat treatment, or a UV curable adhesive tape, an adhesive force of which is weakened by UV irradiation.

Referring to FIG. 8B, a plurality of first conductive members 131, a plurality of second conductive members 133, and a plurality of third conductive members 135 may be bonded to the first adhesive film FI1. In this case, the plurality of the first conductive members 131 and the plurality of the second conductive members 133 may be bonded to the periphery of the first adhesive film FI1, and the plurality of the third conductive members 135 may be bonded between the plurality of the first conductive members 131 and the plurality of the second conductive members 133 in the first horizontal direction (the X direction). The first conductive member 131, the second conductive member 133, and the third conductive member 135 may each include, for example, a conductive material including copper (Cu), aluminum (Al), silver (Ag), gold (Au), tungsten (W), titanium (Ti), or any combination thereof.

Referring to FIG. 8C, the bridge chip 160 may be bonded to the plurality of the third conductive members 135 arranged between the plurality of the first conductive members 131 and the plurality of the second conductive members 133. The bridge chip 160 may include a bridge body 161, a bridge circuit 162, a plurality of first bridge chip pads 163a, and a plurality of second bridge chip pads 163b. A first vertical connection member 171 may be bonded to the upper surface (lower surface in FIG. 8C) of the first bridge chip pad 163a, and a second vertical connection member 173 may be bonded to the upper surface (lower surface in FIG. 8C) of the second bridge chip pad 163b. A first connection terminal 175 may be bonded to a surface opposite to one surface of the first vertical connection member 171 to which the first bridge chip pad 163a is bonded, and a second connection terminal 177 may be bonded to a surface opposite to one surface of the second vertical connection member 173 to which the second bridge chip pad 163b is bonded. For example, the first connection terminal 175 and the second connection terminal 177 may each include a solder ball. In order to bond the bridge chip 160 onto the third conductive member 135, each of the first connection terminal 175 and the second connection terminal 177 may be bonded to a respective third conductive member 135.

Referring to FIGS. 8D and 8E, a first molding material 137, in which the first conductive member 131, the second conductive member 133, the third conductive member 135, and the bridge chip 160 are buried, may be formed. The first molding material 137 may be supplied to the first adhesive film FI1 and then cured. The material included in the first molding material 137 is the same as the material included in the first molding layer 136 described with reference to FIG. 1B. After the first molding material 137 is formed, the upper portion of the first molding material 137 and the upper portion of the bridge body 161 of the bridge chip 160 may be ground. In this case, the limit line of grinding the upper portion of the first molding material 137 and the upper portion of the bridge body 161 may be one surface of each of the first conductive member 131 and the second conductive member 133. The first molding layer 136 may be completed by grinding the first molding material 137. When the first molding layer 136 is completed, one surface of each of the first conductive member 131 and the second conductive member 133, one surface of the first molding layer 136, and one surface of the bridge body 161 may be located on the same plane.

Referring to FIG. 8F, a redistribution structure 110 may be formed on the first molding layer 136. The redistribution structure 110 may include a UBM layer 112, a conductive layer 114, and a passivation layer 116 covering the UBM layer 112 and the conductive layer 114. The passivation layer 116 may completely cover the lower surface (upper surface in FIG. 8F) and the side surface of the conductive layer 114 and may expose the upper surface (lower surface in FIG. 8F) of the conductive layer 114. The redistribution structure 110 illustrated in FIG. 8F may be the same as the redistribution structure 110 described with reference to FIG. 1B.

In order to form the redistribution structure 110, the conductive layer 114 may be first formed on the first molding layer 136. The conductive layer 114 may be formed by a plating process. According to embodiments, a seed layer may be additionally formed on the edge of the conductive layer 114 in order to prevent the metal material of the conductive layer 114 from diffusing into the passivation layer 116 thereafter. After forming the conductive layer 114, a first operation of forming the passivation layer 116 covering the conductive layer 114 and having a via hole, a second operation of forming a UBM via 1121 filling the via hole, and a third operation of forming a UBM pad 1123 integrally formed with the UBM via 1121 and covering a portion of the upper surface of the passivation layer 116 may be performed. The second and third operations of forming the UBM via 1121 and the UBM pad 1123 may include a plating process. In the first operation, the passivation layer 116 may be formed by, for example, lamination, application, chemical vapor deposition (CVD), physical vapor deposition (PVD), or any combination thereof.

Referring to FIG. 8G, after the first adhesive film FI1 and the first carrier substrate CA1 are removed from the first molding layer 136, a second carrier substrate CA2, to which a second adhesive film FI2 is bonded, is bonded to the redistribution structure 110. In this case, the second adhesive film FI2 may be bonded on the passivation layer 116 and the UBM pad 1123. The second adhesive film FI2 and the second carrier substrate CA2 may be substantially the same as the first adhesive film FI1 and the first carrier substrate CA1, respectively.

Referring to FIG. 8H, a portion of the first molding layer 136 may be ground after the second carrier substrate CA2 is turned over. The first and second conductive members (e.g., the first conductive member 131 and the second conductive member 133 of FIG. 8G) may also be ground together with the first molding layer 136. Consequently, a plurality of the first conductive posts 132 and a plurality of the second conductive posts 134 may be completed. In addition, in the process of grinding the first molding layer 136, the third conductive member 135, the first connection terminal 175, and the second connection terminal 177 may be removed. In addition, in the process of grinding the first molding layer 136, a portion of the first vertical connection member 171 and a portion of the second vertical connection member 173 may be removed. Accordingly, a plurality of the first vertical connection conductors 172 and a plurality of the second vertical connection conductors 174 may be completed. The lower surface 172a of the first vertical connection conductor 172 may be bonded to the first bridge chip pad 163a, and the lower surface 174a of the second vertical connection conductor 174 may be bonded to the second bridge chip pad 163b. In addition, the upper surface 172b of the first vertical connection conductor 172 and the upper surface 174b of the second vertical connection conductor 174 may be exposed to the outside.

Referring to FIG. 8I, a plurality of semiconductor chips, including a first semiconductor chip 140 and a second semiconductor chip 150, may be mounted on the first molding layer 136. The first semiconductor chip 140 may include the first chip pad 142a, the second chip pad 142b, the first solder bump 144a, the second solder bump 144b, and a first chip body 146. The second semiconductor chip 150 may include the third chip pad 152a, the fourth chip pad 152b, the third solder bump 154a, the fourth solder bump 154b, and a second chip body 156. The first semiconductor chip 140 and the second semiconductor chip 150 may be mounted so as to partially overlap the bridge chip 160 vertically. The first solder bump 144a may be bonded to the upper surface 132b of the first conductive post 132, and the second solder bump 144b may be bonded to the upper surface 172b of the first vertical connection conductor 172. The third solder bump 154a may be bonded to the upper surface 134b of the second conductive post 134, and the fourth solder bump 154b may be bonded to the upper surface 174b of the second vertical connection conductor 174.

The first solder bump 144a and the third solder bump 154a may enable self-alignment between the first conductive post 132 and the second conductive post 134 corresponding thereto and the first chip pad 142a and the third chip pad 152a corresponding thereto, respectively. In addition, the second solder bump 144b and the fourth solder bump 154b may enable self-alignment between the corresponding first vertical connection conductor 172 and the second vertical connection conductor 174 and the corresponding second chip pad 142b and the fourth chip pad 152b, respectively. The first solder bump 144a, the second solder bump 144b, the third solder bump 154a, and the fourth solder bump 154b may be bonded to the first conductive post 132, the second conductive post 134, the first vertical connection conductor 172, and the second vertical connection structure 174 in a molten state. In this case, the central portions of the first chip pad 142a, the second chip pad 142b, the third chip pad 152a, and the fourth chip pad 152b may not overlap the central portions the corresponding first conductive post 132 and second conductive post 134 and the central portions of the corresponding first vertical connection conductor 172 and second vertical connection conductor 174. However, in the process of solidifying the molten, the first solder bump 144a, the second solder bump 144b, the third solder bump 154a, the fourth solder bump 154b may be self-aligned due to surface tension thereof.

The first solder bump 144a may enable alignment of the central portion of the first conductive post 132 and the central portion of the first chip pad 142a with a first center line L1 without error. In addition, the third solder bump 154a may enable alignment of the central portion of the second conductive post 134 and the central portion of the third chip pad 152a with a fourth center line LA without error.

The second solder bump 144b may enable alignment of the central portion of the first vertical connection conductor 172 and the central portion of the second chip pad 142b with a second center line L2 without error. In addition, the fourth solder bump 154b may enable alignment of the central portion of the second vertical connection conductor 174 and the central portion of the fourth chip pad 152b with a third center line L3 without error.

Referring to FIG. 8J, an underfill material 182 covering a portion of the first molding layer 136 may be formed. The underfill material 182 may fill a portion of the space between the first semiconductor chip 140 and the second semiconductor chip 150. The underfill material 182 may completely cover the first chip pad 142a, the second chip pad 142b, the third chip pad 152a, the fourth chip pad 152b, the first solder bump 144a, and the second solder bump 144b. In addition, the underfill material 182 may partially cover the side surfaces of the first chip body 146 of the first semiconductor chip 140 and the second chip body 156 of the second semiconductor chip 150. The underfill material 182 may be formed by using, for example, a capillary underfill method. More specifically, a material forming the underfill material 182 may be dispensed on the first molding layer 136. The material forming the dispensed underfill material 182 may flow into the space between the first semiconductor chip 140 and the second semiconductor chip 150 and completely cover the second chip pad 142b, the fourth chip pad 152b, the second solder bump 144b, and the fourth solder bump 154b.

Referring to FIG. 8K, a second molding layer 184, covering the underfill material 182, the first semiconductor chip 140, and the second semiconductor chip 150, may be formed. According to embodiments, the upper surface of the second molding layer 184 may be formed to be higher than the uppermost surfaces of the first semiconductor chip 140 and the second semiconductor chip 150. In this case, the upper portion of the second molding layer 184 may be ground so that the upper surface of the second molding layer 184 and the uppermost surfaces of the first semiconductor chip 140 and the second semiconductor chip 150 are located on the same plane.

Referring to FIGS. 8L and 8M, after the second carrier substrate CA2 and the second adhesive film FI2 are removed from the redistribution structure 110, a ring frame RF may be bonded to the upper surfaces of the first semiconductor chip 140 and the second semiconductor chip 150 and the upper surface of the second molding layer 184. An adhesive material may be applied to one surface of the ring frame RF so that the ring frame RF is partially bonded to the upper surfaces of the first semiconductor chip 140 and the second semiconductor chip 150 and the upper surface of the second molding layer 184. After the ring frame RF is bonded to the upper surfaces of the first semiconductor chip 140 and the second semiconductor chip 150 and the upper surface of the second molding layer 184, the ring frame RF may be turned over so that the lower surface of the redistribution structure 110 faces the vertical direction (the Z direction).

Referring to FIGS. 8M and 8N, after an external connection terminal 190 is bonded to the UBM layer 112, the ring frame RF may be turned over again so that upper surfaces of the first semiconductor chip 140 and the second semiconductor chip 150 face the vertical direction (the Z direction). Thereafter, the semiconductor package 10 may be completed by removing the ring frame RF. The external connection terminal 190 may have, for example, a flip-chip connection structure with a grid array, such as a solder ball, conductive bump, or pin grid array, a ball grid array, or a land grid array.

While non-limiting example embodiments of the present disclosure have been particularly shown and described, it will be understood that various changes in form and details may be made therein without departing from the spirit and scope of the present disclosure.

What is claimed is:

1. A semiconductor package comprising:
a redistribution structure comprising:
a passivation layer that is a single layer structure;
an under bump metallurgy (UBM) layer on a portion of a lower surface of the passivation layer; and
a conductive layer in contact with the UBM layer and exposed from an upper surface of the passivation layer opposite to the lower surface of the passivation layer;
a bridge chip on the redistribution structure and comprising a bridge chip pad;
a first molding layer sealing the bridge chip on the redistribution structure;
a plurality of conductive posts spaced apart from each other in a horizontal direction within the first molding layer, the bridge chip being between the plurality of conductive posts, and each of the plurality of conductive posts comprising a first surface and a second surface opposite to the first surface; and
a plurality of semiconductor chips on the first molding layer and the bridge chip, each of the plurality of semiconductor chips comprising a chip pad and a solder bump,
wherein the first surface of each of the plurality of conductive posts is bonded to the conductive layer, and the second surface of each of the plurality of conductive posts is bonded to the solder bump of a respective one of the plurality of semiconductor chips, and
wherein the solder bump is configured to enable self-alignment between one conductive post from among the plurality of conductive posts and the chip pad.

2. The semiconductor package of claim 1, wherein an upper surface of the conductive layer is in contact with the first surface of each of the plurality of conductive posts, and
a lower surface of the conductive layer, opposite to the upper surface of the conductive layer, is in contact with the UBM layer.

3. The semiconductor package of claim 1, wherein a center line passing through a center of the chip pad is located within 10 micrometers to 100 micrometers in the horizontal direction from a center line passing through a center of one of the plurality of conductive posts.

4. The semiconductor package of claim 1, wherein the plurality of conductive posts each have a single cylindrical shape.

5. The semiconductor package of claim 1, further comprising a second molding layer on the first molding layer and sealing the plurality of semiconductor chips,
wherein an upper surface of the second molding layer and an upper surface of each of the plurality of semiconductor chips are on a same plane.

6. The semiconductor package of claim 5, wherein the second molding layer comprises a same material as a material of the first molding layer.

7. The semiconductor package of claim 1, wherein a length of each of the plurality of conductive posts in a vertical direction is equal to a length of the first molding layer in the vertical direction.

8. The semiconductor package of claim 1, wherein the plurality of semiconductor chips comprise a first semiconductor chip and a second semiconductor chip apart from the first semiconductor chip in the horizontal direction, and
the first semiconductor chip comprises a logic semiconductor chip, and the second semiconductor chip comprises a high bandwidth memory (HBM) chip.

9. The semiconductor package of claim 8, wherein the bridge chip is configured to provide an electrical connection path between the first semiconductor chip and the second semiconductor chip.

10. The semiconductor package of claim 1, further comprising an underfill material on the first molding layer and filling a space between the first molding layer and the plurality of semiconductor chips,
wherein the underfill material surrounds the chip pad and the solder bump.

11. The semiconductor package of claim 1, wherein the UBM layer comprises:
a UBM via, wherein a diameter of the UBM via decreases as a distance to the bridge chip decreases; and
a UBM pad on the lower surface of the passivation layer.

12. A semiconductor package comprising:
a redistribution structure comprising:
a passivation layer that is a single layer structure;
an under bump metallurgy (UBM) layer on a portion of a lower surface of the passivation layer; and
a conductive layer in contact with the UBM layer and exposed from an upper surface of the passivation layer opposite to the lower surface of the passivation layer;
a plurality of semiconductor chips spaced apart on the redistribution structure in a horizontal direction and each comprising chip pads, first solder bumps, and second solder bumps;
a bridge chip between the plurality of semiconductor chips and the redistribution structure and comprising a plurality of bridge chip pads;
a plurality of conductive posts spaced apart from each other in the horizontal direction, the bridge chip being between the plurality of conductive posts and each of the plurality of conductive posts comprises a first surface bonded to the conductive layer and a second surface bonded to a respective one of the first solder bumps;
a plurality of vertical connection conductors between the plurality of semiconductor chips and the bridge chip, each of the plurality of vertical connection conductors comprising:
a third surface bonded to a respective one of the plurality of bridge chip pads; and
a fourth surface bonded to a respective one of the second solder bumps; and
a first molding layer disposed on the redistribution structure and sealing the bridge chip, the plurality of conductive posts, and the plurality of vertical connection conductors,
wherein the first solder bumps are configured to enable self-alignment between the plurality of conductive posts and at least some of the chip pads.

13. The semiconductor package of claim 12, wherein the plurality of conductive posts overlap with the plurality of semiconductor chips in a vertical direction.

14. The semiconductor package of claim 12, wherein the second surface of each of the plurality of conductive posts and the fourth surface of each of the plurality of vertical connection conductors are on a same plane.

15. The semiconductor package of claim 12, wherein the plurality of conductive posts and the plurality of vertical connection conductors each have a single cylindrical shape, and
a length of each of the plurality of conductive posts in a vertical direction is equal to a length of each of the plurality of vertical connection conductors in the vertical direction.

16. The semiconductor package of claim 15, wherein a diameter of each of the plurality of conductive posts is greater than a diameter of each of the plurality of vertical connection conductors.

17. The semiconductor package of claim 12, wherein a distance in the horizontal direction between a conductive post closest to a periphery of the bridge chip, among the plurality of conductive posts, and a vertical connection conductor closest to the periphery of the bridge chip, among the plurality of vertical connection conductors, is greater than a distance in the horizontal direction between a pair of conductive posts that are adjacent to each other among the plurality of conductive posts.

18. The semiconductor package of claim 12, wherein a distance in the horizontal direction between a conductive post closest to a periphery of the bridge chip, among the plurality of conductive posts, and a vertical connection conductor closest to the periphery of the bridge chip, among the plurality of vertical connection conductors, is equal to a distance in the horizontal direction between a pair of conductive posts adjacent to each other among the plurality of conductive posts.

19. A semiconductor package comprising:
a redistribution structure comprising:
a passivation layer that is a single layer structure;
an under bump metallurgy (UBM) layer on a portion of a lower surface of the passivation layer; and
a conductive layer in contact with the UBM layer and exposed from an upper surface of the passivation layer opposite to the lower surface of the passivation layer;
a first semiconductor chip on the redistribution structure and comprising a first solder bump, a second solder bump, a first chip pad bonded to the first solder bump, and a second chip pad bonded to the second solder bump;
a second semiconductor chip on the redistribution structure, spaced apart from the first semiconductor chip in a horizontal direction, and comprising a third solder bump, a fourth solder bump, a third chip pad bonded to the third solder bump, and a fourth chip pad bonded to the fourth solder bump;
a bridge chip between the redistribution structure and the first semiconductor chip and comprising bridge chip pads and a bridge circuit electrically connected to the bridge chip pads, the bridge chip configured to provide an electrical connection path between the first semiconductor chip and the second semiconductor chip;
a first sealing layer sealing the bridge chip;
a first conductive post passing through the first sealing layer in a vertical direction on one side of the bridge chip; and
a second conductive post passing through the first sealing layer in the vertical direction on another side of the bridge chip opposite to the one side,
wherein the first conductive post comprises a lower surface and an upper surface opposite to the lower surface of the first conductive post, wherein the lower surface is bonded to the conductive layer and the upper surface is bonded to the first solder bump,
wherein the second conductive post comprises a lower surface and an upper surface opposite to the lower surface of the second conductive post, wherein the lower surface is bonded to the conductive layer and the upper surface is bonded to the third solder bump,
wherein a horizontal distance between the second solder bump and the bridge chip is smaller than a horizontal distance between the first solder bump and the bridge chip,
wherein a horizontal distance between the fourth solder bump and the bridge chip is smaller than a horizontal distance between the third solder bump and the bridge chip,
wherein the first solder bump is configured to enable self-alignment between the first conductive post and the first chip pad, and
wherein the third solder bump is configured to enable self-alignment between the second conductive post and the second chip pad.

20. The semiconductor package of claim 19, further comprising:
a first vertical connection conductor passing through the first sealing layer in the vertical direction between the bridge chip and the first semiconductor chip; and
a second vertical connection conductor passing through the first sealing layer in the vertical direction between the bridge chip and the second semiconductor chip,
wherein the first vertical connection conductor comprises a lower surface bonded to a first one of the bridge chip pads and an upper surface bonded to the second solder bump, and
the second vertical connection conductor comprises a lower surface bonded to a second one of the bridge chip pads and an upper surface bonded to the fourth solder bump.
